(19) United States
(12) Patent Application Publication
(10) Pub. No.: US 2024/0274526 A1
(43) Pub. Date: Aug. 15, 2024

(54) Memory Circuitry And Methods Used In Forming Memory Circuitry

(71) Applicant: Micron Technology, Inc., Boise, ID (US)

(72) Inventors: Tsuyoshi Tomoyama, Higashihiroshima (JP); Protyush Sahu, Boise, ID (US); Hiromitsu Oshima, Higashihiroshima (JP); Jeffery B. Hull, Boise, ID (US); Satoru Sugiyama, Higashihiroshima (JP); Soichi Sugiura, Bristow, VA (US)

(73) Assignee: Micron Technology, Inc., Boise, ID (US)

(21) Appl. No.: 18/440,404

(22) Filed: Feb. 13, 2024

Related U.S. Application Data
(60) Provisional application No. 63/445,431, filed on Feb. 14, 2023.

(51) Int. Cl. H01L 23/522; H01L 23/528; H10B 12/00

(52) U.S. Cl. CPC H01L 23/5226; H01L 23/5283; H10B 12/03; H10B 12/05; H10B 12/482; H10B 12/485

(57) ABSTRACT

A method used in forming memory circuitry comprises forming transistors of individual memory cells. The transistors individually comprise one source/drain region and another source/drain region. The one and another source/drain regions comprise conductively-doped monocrystalline semiconductive material. A channel region is between the one and the another source/drain regions. A conductive gate is operatively proximate the channel region. Masking material is formed directly above the one and another source/drain regions. The masking material has openings there-through that extend to and are individually directly above individual of the one source/drain regions. Conductively-doped monocrystalline semiconductor material is epitaxially grown from the conductively-doped monocrystalline semiconductive material of the individual one source/drain regions within individual of the openings to form conductive islands that are individually directly above and directly against the individual one source/drain regions in the individual openings. Storage elements of the individual memory cells are formed. The storage elements individually are above and electrically coupled to the individual one source/drain regions through individual of the conductive islands comprising the epitaxially-grown conductively-doped monocrystalline semiconductor material. Other embodiments, including structure, are disclosed.

### TECHNICAL FIELD

Embodiments disclosed herein pertain to memory circuitry and to methods used in forming memory circuitry.

### BACKGROUND

Memory is one type of integrated circuitry and is used in computer systems for storing data. Memory may be fabricated in one or more arrays of individual memory cells. Memory cells may be written to, or read from, using digitlines (which may also be referred to as bitlines, data lines, or sense lines) and access lines (which may also be referred to as wordlines). The digitlines may conductively interconnect memory cells along columns of the array, and the access lines may conductively interconnect memory cells along rows of the array. Each memory cell may be uniquely addressed through the combination of a digitline and an access line.

Memory cells may be volatile, semi-volatile, or non-volatile. Non-volatile memory cells can store data for extended periods of time in the absence of power. Non-volatile memory is conventionally specified to be memory having a retention time of at least about 10 years. Volatile memory dissipates and is therefore refreshed/rewritten to maintain data storage. Volatile memory may have a retention time of milliseconds or less. Regardless, memory cells are configured to retain or store memory in at least two different selectable states. In a binary system, the states are considered as either a “0” or a “1”. In other systems, at least some individual memory cells may be configured to store more than two levels or states of information.

A capacitor is one type of electronic component that may be used in a memory cell. A capacitor has two electrical conductors separated by electrically insulating material. Energy as an electric field may be electrostatically stored within such material. Depending on composition of the insulator material, that stored field will be volatile or non-volatile. For example, a capacitor insulator material including only SiO₂ will be volatile. One type of non-volatile capacitor is a ferroelectric capacitor which has ferroelectric material as at least part of the insulating material. Ferroelectric materials are characterized by having two stable polarized states and thereby can comprise programmable material of a capacitor and/or memory cell. The polarization state of the ferroelectric material can be changed by application of suitable programming voltages and remains after removal of the programming voltage (at least for a time). Each polarization state has a different charge-stored capacitance from the other, and which ideally can be used to write (i.e., store) and read a memory state without reversing the polarization state until such is desired to be reversed. Less desirable, in some memory having ferroelectric capacitors the act of reading the memory state can reverse the polarization. Accordingly, upon determining the polarization state, a re-write of the memory cell is conducted to put the memory cell into the pre-read state immediately after its determination. Regardless, a memory cell incorporating a ferroelectric capacitor ideally is non-volatile due to the bi-stable characteristics of the ferroelectric material that forms a part of the capacitor. Other programmable materials may be used as a capacitor insulator to render capacitors non-volatile.

A field effect transistor is another type of electronic component that may be used in a memory cell. These transistors comprise a pair of conductive source/drain regions having a semiconductive channel region there-between. A conductive gate is adjacent the channel region and separated there-from by a thin gate insulator. Application of a suitable voltage to the gate allows current to flow from one of the source/drain regions to the other through the channel region. When the voltage is removed from the gate, current is largely prevented from flowing through the channel region. Field effect transistors may also include additional structure, for example a reversibly programmable charge-storage region as part of the gate construction between the gate insulator and the conductive gate. Regardless, the gate insulator may be programmable, for example being ferroelectric.

### BRIEF DESCRIPTION OF THE DRAWINGS

FIGS. 1-6 are diagrammatic cross-sectional views of a portion of a DRAM construction in fabrication in accordance with some embodiments of the invention.

FIGS. 7-27 are diagrammatic sequential sectional views of the construction of FIGS. 1-6 in subsequent processing, or alternate embodiments, in accordance with some embodiments of the invention.

### DETAILED DESCRIPTION OF EXAMPLE EMBODIMENTS

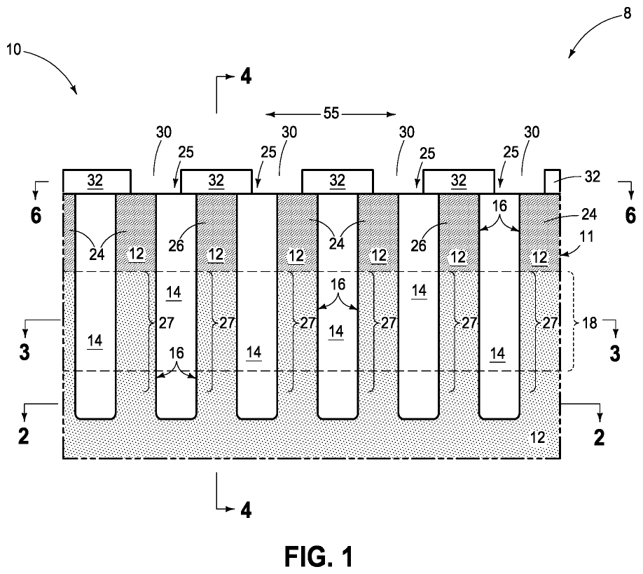

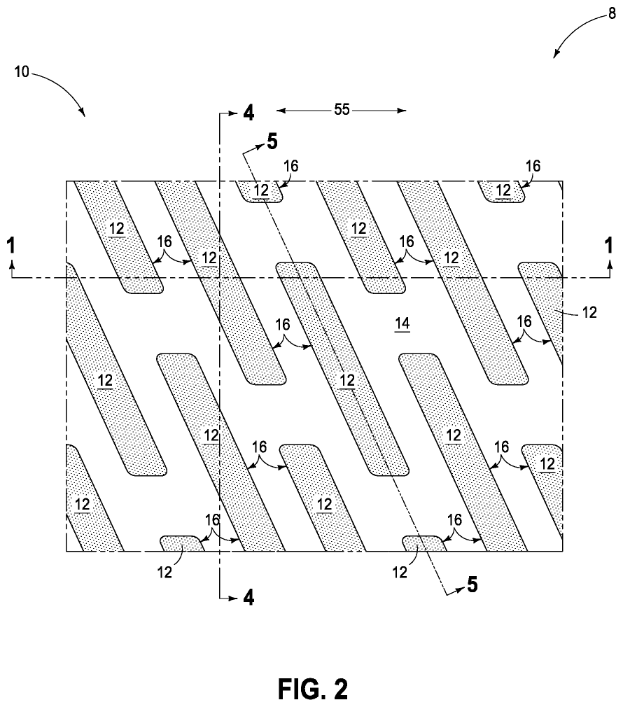

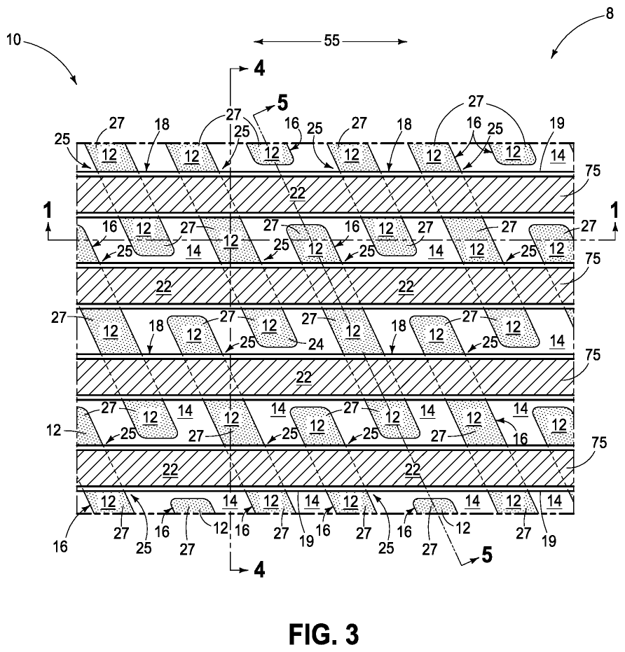

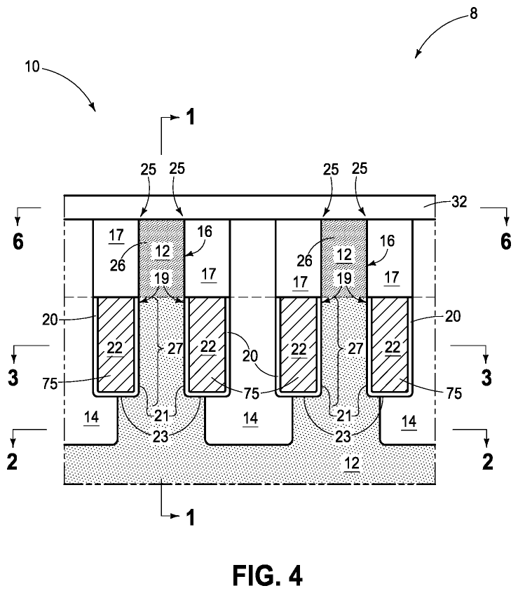

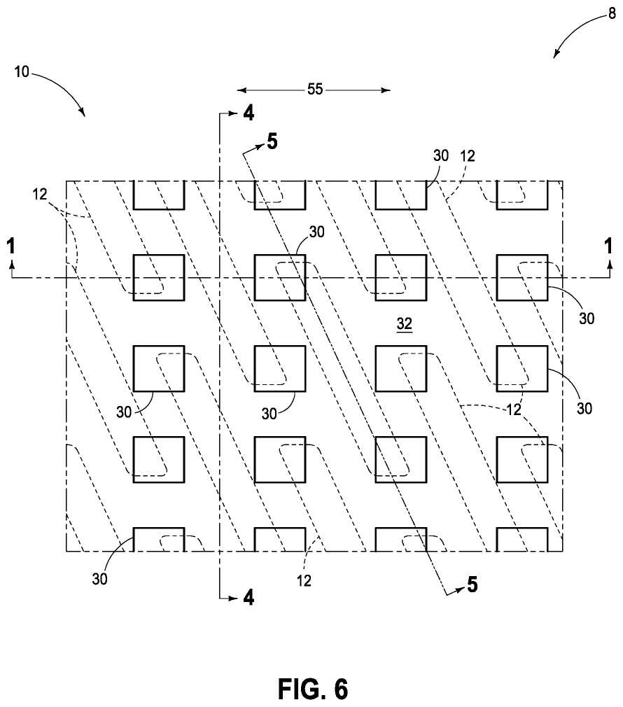

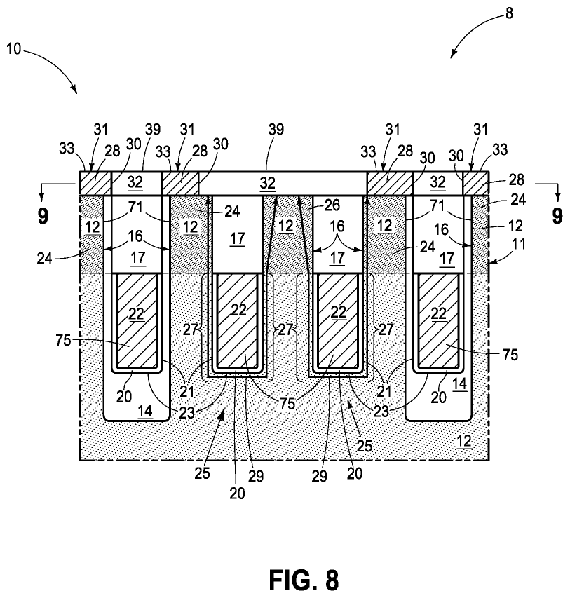

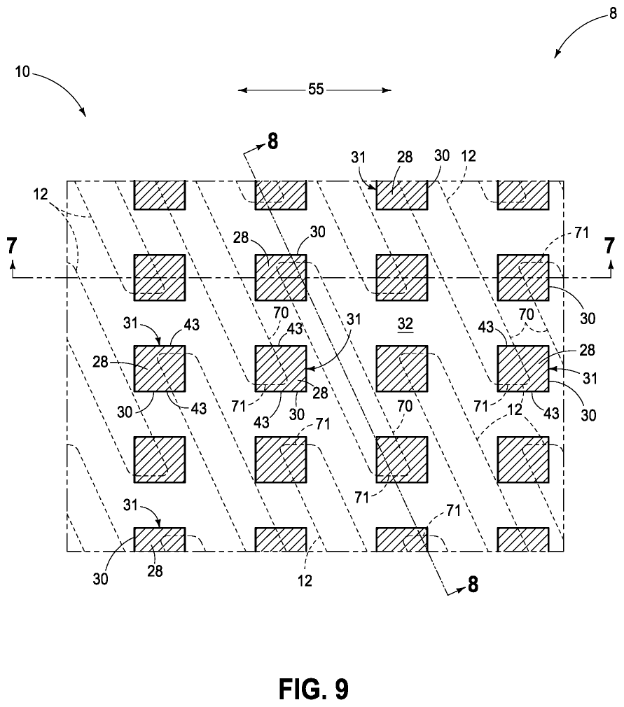

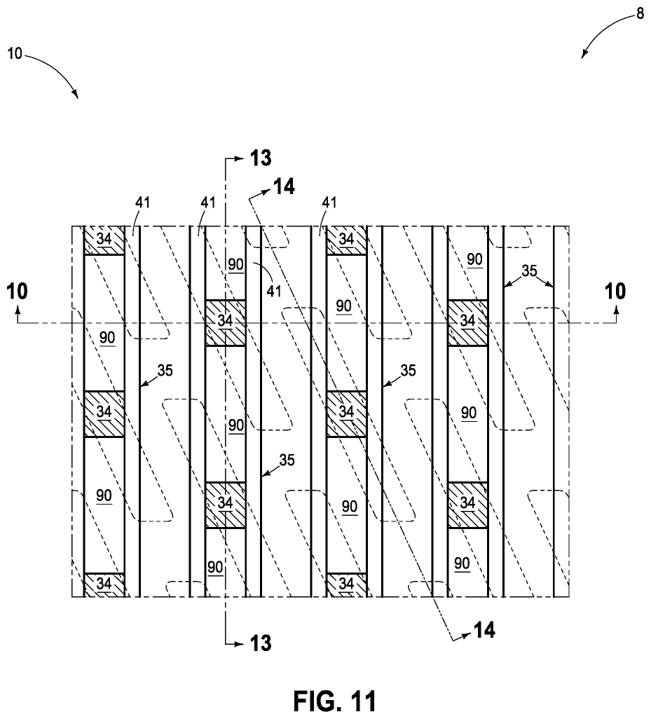

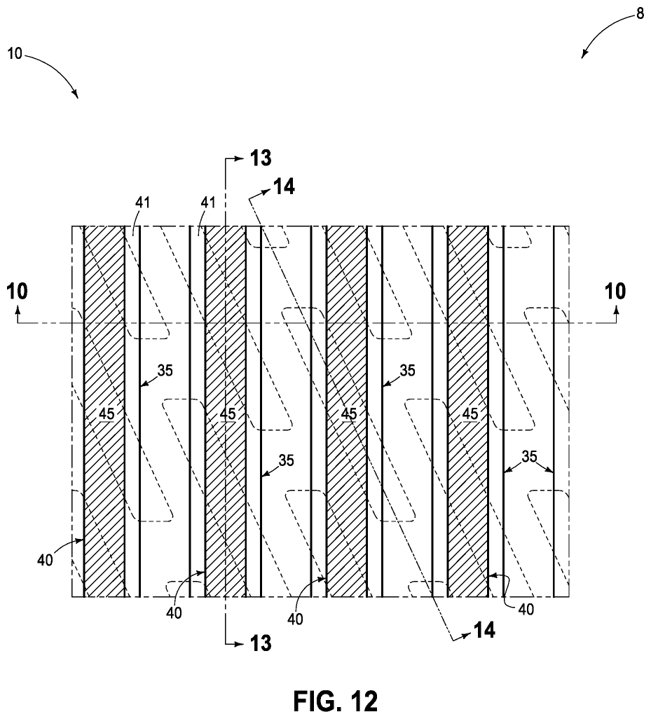

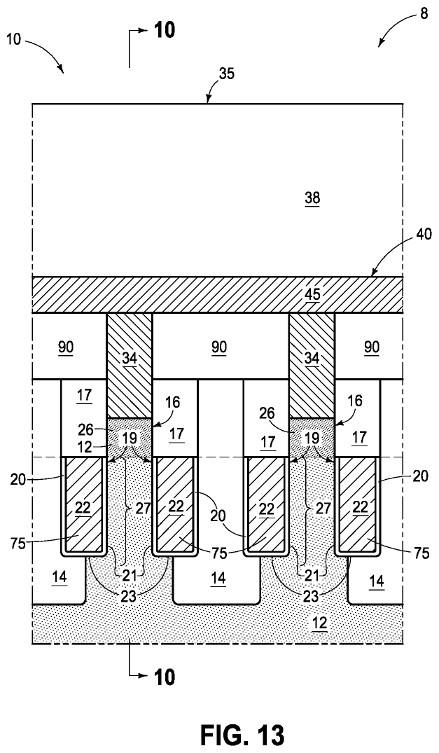

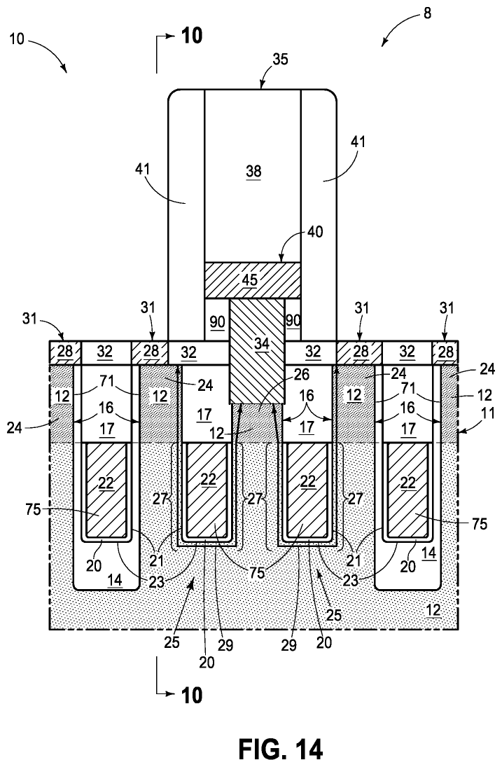

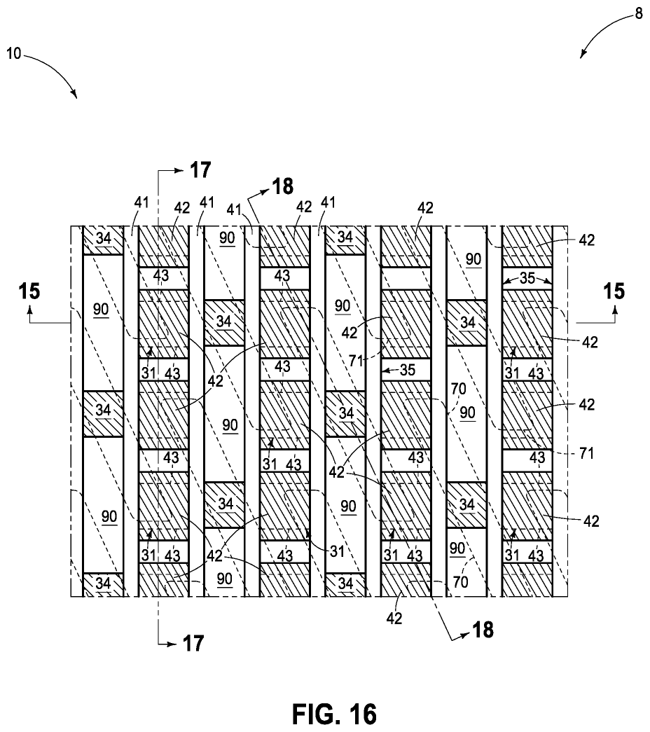

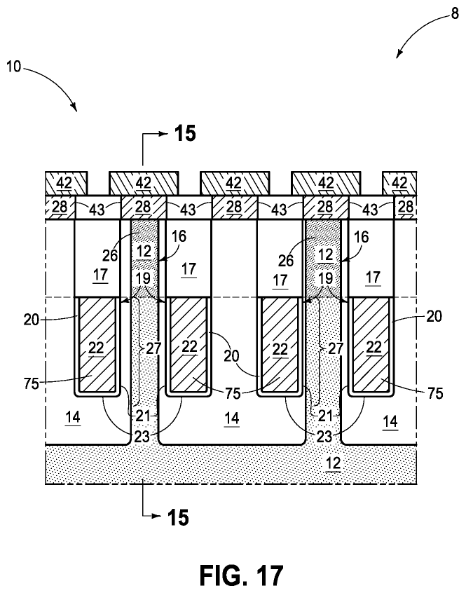

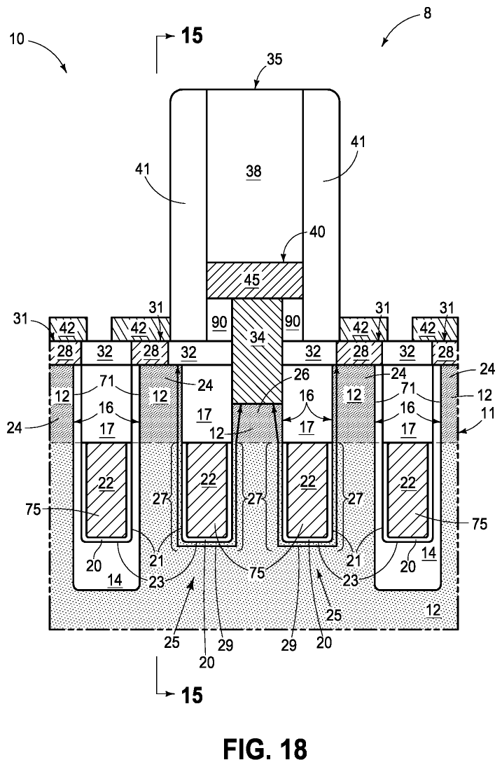

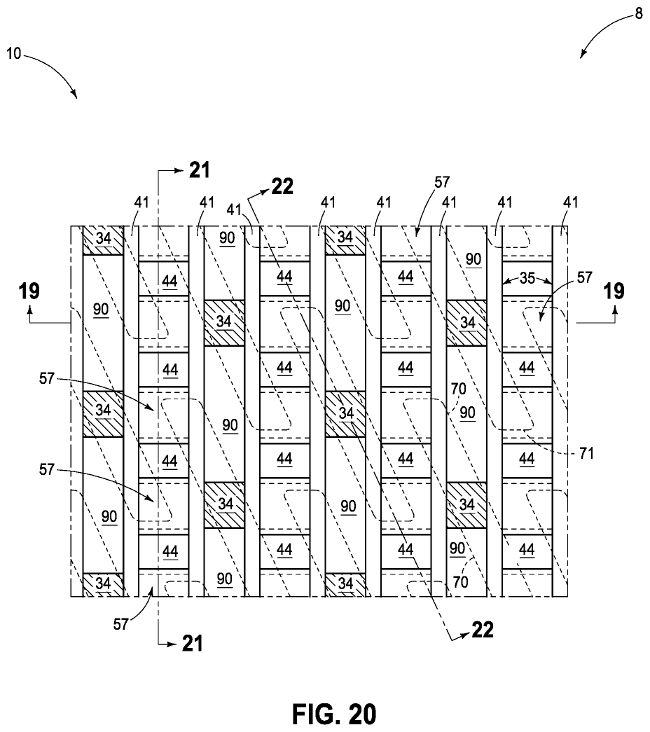

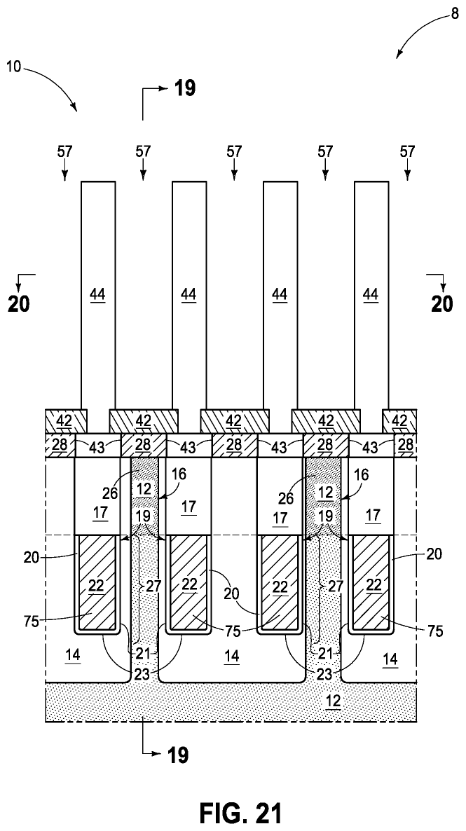

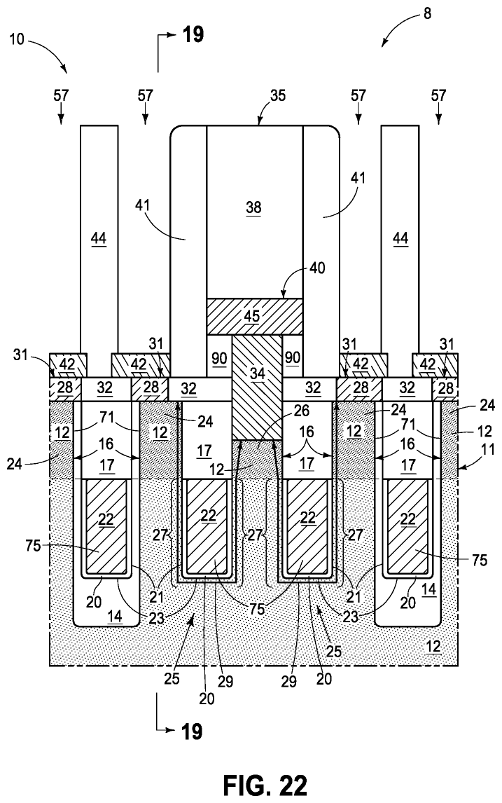

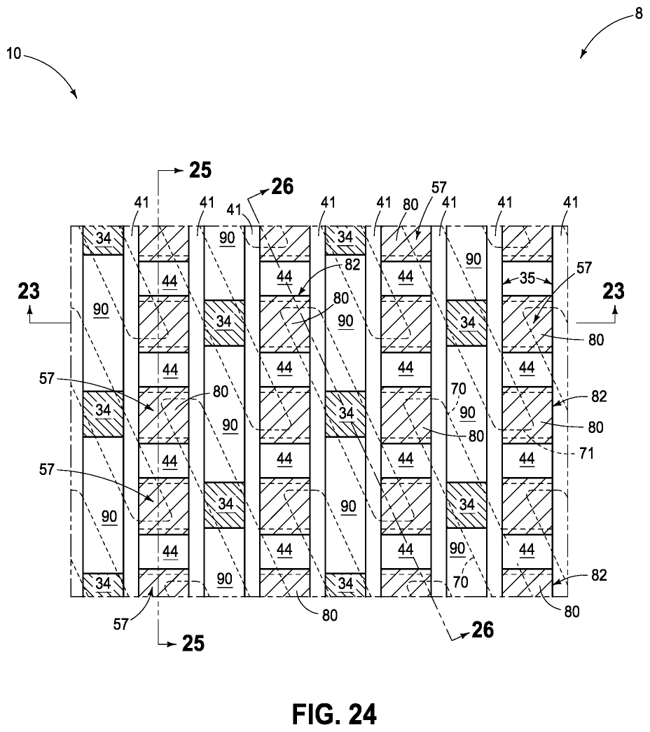

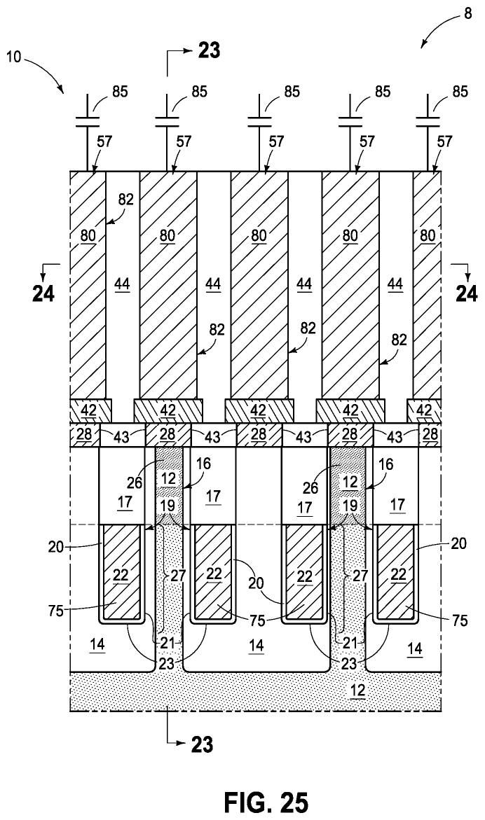

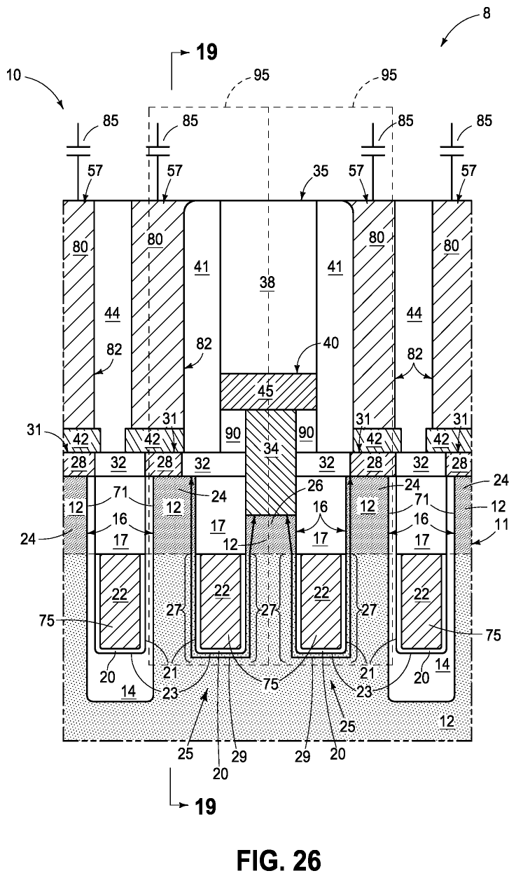

Example embodiments are described with reference to FIGS. 1-27. FIGS. 1-6 show an example fragment of a substrate construction 8 comprising an array or array area 10 in the process of fabrication relative to a base substrate 11. Substrate 11 may comprise any one or more of conductive/conductor/conducting, semiconductive/semiconductor/semiconducting, and insulative/insulator/insulating (i.e., electrically herein) materials. Materials may be aside, elevationally inward, or elevationally outward of the FIGS. 1-6-depicted materials. For example, other partially or wholly fabricated components of integrated circuitry may be provided somewhere above, about, or within base substrate 11. Control and/or other peripheral circuitry for operating components within a memory array may also be fabricated and may or may not be wholly or partially within a memory array or sub-array. Further, multiple sub-arrays may also be fabricated and operated independently, in tandem, or otherwise relative one another. As used in this document, a “sub-array” may also be considered as an array.

Base substrate 11 comprises semiconductive material 12 (e.g., appropriately and variously doped monocrystalline and/or polycrystalline silicon, Ge, SiGe, GaAs, and/or other existing or future-developed semiconductive material), trench isolation regions 14 (e.g., silicon nitride atop silicon dioxide), and active area regions 16 comprising suitably and variously-doped semiconductive material 12. Construction 8 comprises transistors 25 individually comprising one source/drain region 24 and another source/drain region 26, a channel region 27 between the one and the another source/drain regions, and a conductive gate 22 (e.g., conductively-doped semiconductor material and/or metal material, including for example elemental W, Ru, and/or Mo) operatively proximate channel region 27 (e.g., a gate insulator 20 being between the conductive gate 22 and channel region 27, for example silicon dioxide and/or silicon nitride). Conductive gate 22 comprises part of one of a plurality of conductive-gate lines 75 in substrate 11 and that extend along a row direction 55. Transistors 25 are shown as being recessed access devices, with example construction 8 showing such recessed access devices grouped in individual pairs of such devices. Individual recessed access devices/transistors 25 include a buried access line construction 18, for example that is within a trench 19 in semiconductive material 12. Constructions 18 comprise conductive gate 22. Gate insulator 20 is along sidewalls 21 and a base 23 of individual trenches 19 between conductive gate 22 and semiconductive material 12. Insulator material 17 (e.g., silicon dioxide and/or silicon nitride) is within trenches 19 above materials 20 and 22. One source/drain region 24 and another source/drain region 26 are in upper portions of semiconductive material 12 on opposing sides of individual trenches 19 (e.g., regions 24, 26 being laterally-outward of and higher than access line constructions 18). Each of source/drain regions 24, 26 has at least a part thereof having a conductivity-increasing dopant therein that is of maximum concentration of such conductivity-increasing dopant within the respective source/drain region 24, 26, for example to render such part to be conductive (e.g., having a maximum dopant concentration of at least 10¹⁸ atoms/cm³). Accordingly, all or only a part of each source/drain region 24, 26 may have such maximum concentration of conductivity-increasing dopant. One source/drain region 24 and another source/drain region 26 comprise conductively-doped monocrystalline semiconductive material (e.g., predominantly at least one of silicon or germanium that is conductively-doped to be n-type or p-type conductive). Source/drain regions 24 and/or 26 may include other doped regions (not shown), for example halo regions, LDD regions, etc.

In the example embodiment, one of the source/drain regions (e.g., another source/drain region 26) of the pair of source/drain regions in individual of the pairs of transistors 25 is laterally between conductive gates 22 and is shared by the pair of devices 25. Others of the source/drain regions (e.g., one source/drain region 24) of the pair of source/drain regions are not shared by the pair of transistors 25. Thus, in the example embodiment, each active area region 16 comprises two transistors 25 (e.g., one pair of transistors 25), with each sharing a central source/drain region 26.

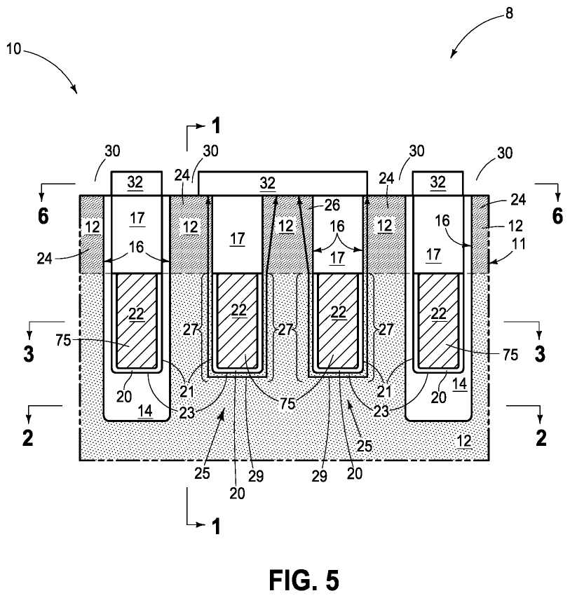

Example channel region 27 is in semiconductive material 12 below pair of source/drain regions 24, 26 along trench sidewalls 21 and around trench base 23. Channel region 27 may be undoped or may be suitably doped with a conductivity-increasing dopant likely of the opposite conductivity-type of the dopant in source/drain regions 24, 26. When suitable voltage is applied to gate material 22 of an access line construction 18, a conductive channel forms (e.g., along a channel current-flow line/path 29 [FIG. 5] within channel region 27 proximate gate insulator 20 such that current is capable of flowing between a pair of source/drain regions 24 and 26 under the access line construction 18 within an individual active area region 16. Stippling is diagrammatically shown to indicate primary conductivity-modifying dopant concentration (regardless of type), with denser stippling indicating greater dopant concentration and lighter stippling indicating lower dopant concentration. Conductivity-modifying dopant may be, and would likely be, in other portions of material 12 as shown. Only two different stippling densities are shown in material 12 for convenience, and additional dopant concentrations may be used, and constant dopant concentration is not required in any region.

Masking material 32 has been formed directly above one and another source/drain regions 24, 26. In one embodiment, masking material 32 is insulative (e.g., silicon dioxide) and one such embodiment remains in the finished-circuitry construction. Regardless, masking material 32 has openings 30 there-through that extend to and are individually directly above individual one source/drain regions 24.

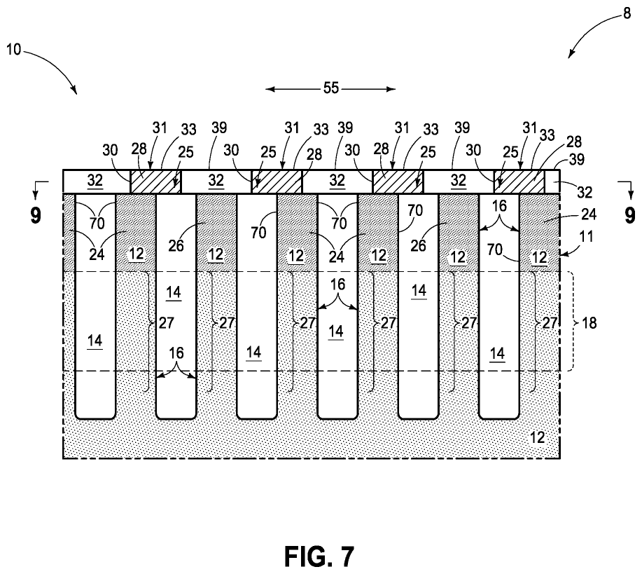

Referring to FIGS. 7-9, conductively-doped monocrystalline semiconductor material 28 has been epitaxially grown from the conductively-doped monocrystalline semiconductive material of one source/drain regions 24 within individual openings 30 to form conductive islands 31 that are individually directly above and directly against individual one source/drain regions 24 in individual openings 30. Material 28 initially will likely only epitaxially grow from the top surface of one source/drain regions 24, and then grow vertically and laterally from itself to fill lateral confines of openings 30 as it grows vertically. In one embodiment and as shown, masking material 32 masks another source/drain regions 26 during the epitaxially growing so no conductively-doped monocrystalline semiconductor material grows therefrom. Conductive islands 31 may have tops 33 that are below, above, or elevationally-coincident with a top 39 of masking material 32. If tops 33 are to be at or below top 39, conductively-doped monocrystalline semiconductor material 28 may be initially so grown. Alternately, conductively-doped monocrystalline semiconductor material 28 may be initially epitaxially grown to have tops 33 that are above tops 39 (not shown), followed by planarizing material 28 back thereto. Conductive islands 31 may be considered as having opposing sides 43. The artisan is capable of selecting suitable conditions for epitaxially growing conductively-doped monocrystalline semiconductor material 28 depending on its composition. For example, and by way of example only, conductively n-type-doped monocrystalline silicon can be epitaxially grown from monocrystalline silicon using dichlorosilane, HCl, and phosphine at temperature of 500° C. to 800° C. and pressure of 5 Torr to 500 Torr.

In one embodiment, the epitaxially growing forms conductively-doped monocrystalline semiconductor material 28 to extend laterally-outward beyond a longest side 70 of individual one source/drain regions 24, and in one embodiment to extend laterally-outward beyond a longitudinal end 71 of individual one source/drain regions 24 (due to size, shape, and positions of openings 30). Conductively-doped monocrystalline semiconductor material 28 in the example embodiment is shown extending laterally-outward beyond only one of two opposing longest sides 70 of individual one source/drain regions 24 and may alternately so extend beyond both (not shown). In one embodiment, the epitaxially growing forms conductively-doped monocrystalline semiconductor material 28 to at least predominantly (greater than 50% up to and in including 100% in volume) have greater conductivity-increasing-dopant therein than is at least predominantly in individual one source/drain regions 24. In one such embodiment, the greater conductivity-increasing-dopant is by a factor of at least 10. In one embodiment, conductively-doped monocrystalline semiconductor material 28 and the conductively-doped monocrystalline semiconductive material of one source/drain regions 24 are of the same composition but for quantity of the conductivity-increasing-dopant, and in one such embodiment the same composition at least predominantly comprises elemental silicon. As an example, conductivity-dopant concentration in one source/drain regions 24 is 1×10¹⁸ atoms/cm³ to 1×10²⁰ atoms/cm³ and in conductively-doped monocrystalline semiconductor material 28 is 1×10²¹ atoms/cm³ to 1×10²³ atoms/cm³.

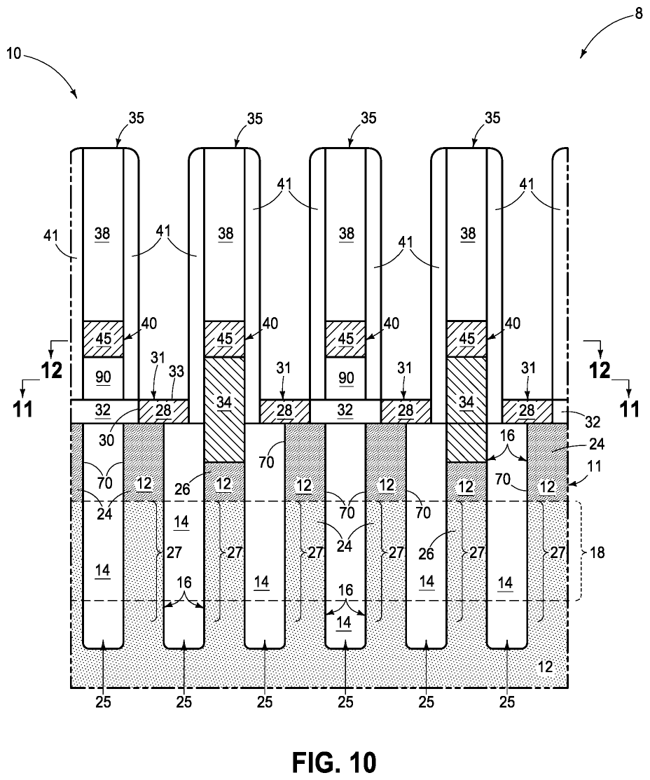

Referring to FIGS. 10-14, and in one embodiment, digitline structures 35 have been formed and are individually directly electrically coupled to another source/drain regions 26 of multiple of transistors 25. Digitline structures 35 individually comprise a conductive digitline 40 (e.g., comprising conductive metal material 45) that is directly electrically coupled to individual another source/drain regions 26 through individual conducting vias 34 that have insulative material 90 (e.g., silicon nitride and/or silicon dioxide) there-between. Digitline structures 35 comprise an insulator material 38 thereatop and anisotropically-etched insulative sidewall spacers 41 (e.g., silicon nitride and/or silicon dioxide) on each side thereof. Spacers 41 may individually comprise multiple different composition materials some or each of which may be separately anisotropically etched.

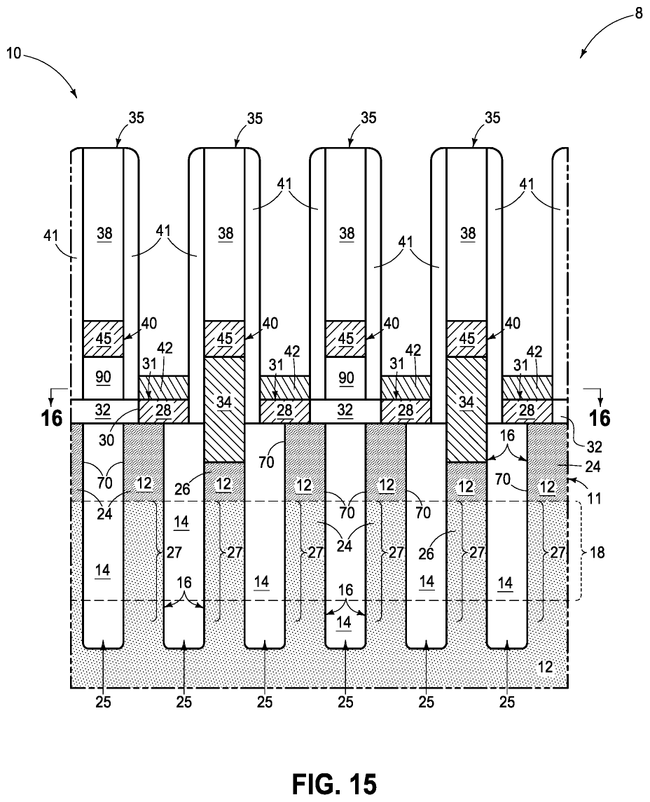

Storage elements of individual memory cells are ultimately formed. Such storage elements individually are above and electrically coupled (e.g., directly electrically coupled) to individual one source/drain regions 24 through individual conductive islands 31 that comprise epitaxially-grown conductively-doped monocrystalline semiconductor material 28. In one such embodiment, conducting material is formed directly above and directly electrically coupled to individual conductive islands 31, with such conducting material being of different composition from that of conductively-doped monocrystalline semiconductor material 28. In one such latter embodiment, the conducting material comprises conductively-doped semiconducting material directly above and directly against conductively-doped monocrystalline semiconductor material 28 of conductive island 31 and conductive metal material directly above and directly against the conductively-doped semiconducting material. One such example is next-described with respect to FIGS. 15-26.

Referring to FIGS. 15-18, and in one embodiment, conductively-doped semiconducting material 42 has been formed atop conductively-doped monocrystalline semiconductor material 28 of individual conductive islands 31. By way of examples, material 42 may be deposited directly against material 28 and subtractively etched, or material 42 may be epitaxially grown from material 28. Materials 42 and 28 may be of the same or different composition(s) relative one another. Regardless, and in one such embodiment as shown, conductively-doped semiconducting material 42 extends laterally-outward beyond a side 43 of epitaxially-grown conductively-doped monocrystalline semiconductor material 28 of conductive islands 31 (e.g., beyond two opposing sides 43 as shown).

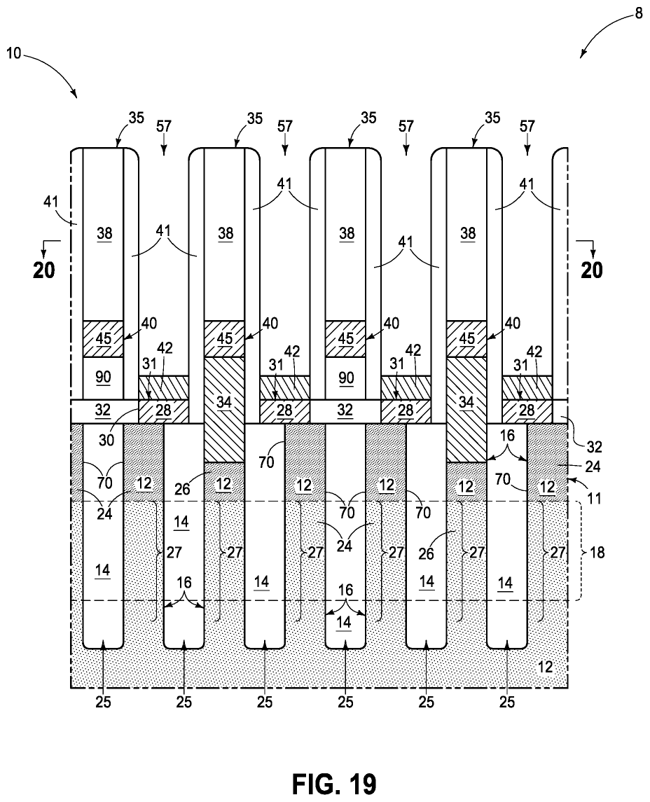

Referring to FIGS. 19-22, insulative material 44 (e.g., silicon dioxide and/or silicon nitride) has been formed between digitline structures 35 and contact openings 57 have then been formed there-through to conductively-doped semiconducting material 42. Insulative material 44 may be planarized back to the tops of material 38 (as shown). Contact openings 57 may taper laterally inward and/or laterally outward (not shown). Contact openings 57 in horizontal cross-section may be of the same size and/or shape that of material 42 and/or 28 (same shape, different sizes being shown). In embodiments where conductively-doped semiconducting material 42 is formed, such may be formed before or after forming insulative material 44 with its contact openings 57.

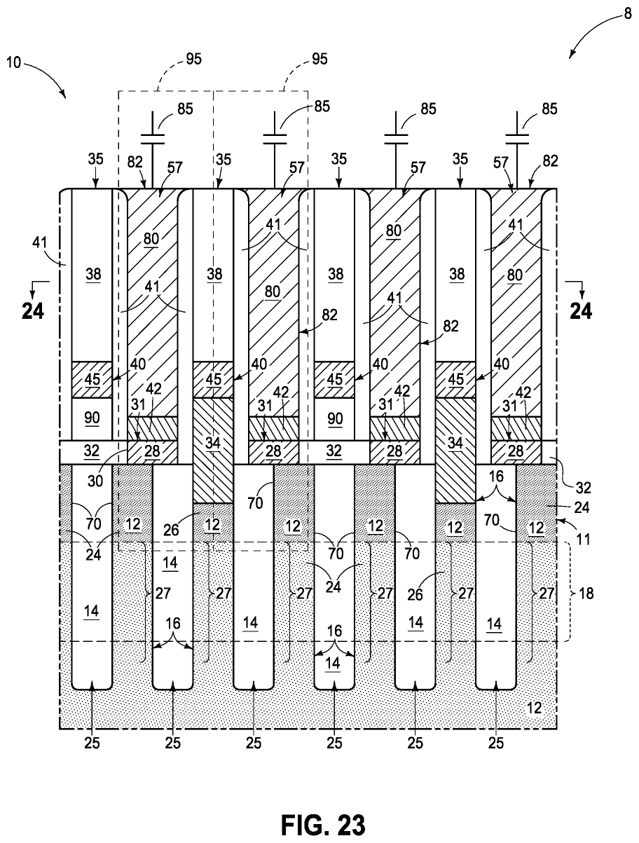

Referring to FIGS. 23-26, conductive metal material 80 has been formed directly above and directly against conductively-doped semiconducting material 42, thus forming individual conductive-via constructions 82 (e.g., comprising materials 80, 42, and 28). Storage elements 85 (e.g., capacitors) have been formed (e.g., directly electrically coupled to individual conductive-via constructions 82), thus forming individual memory cells 95 (e.g., that comprise a transistor 25 and a storage element 85). Such is but one example embodiment where storage elements 85 are individually above and electrically coupled (e.g., directly coupled) to individual one source/drain regions 24 through individual conductive islands 31 comprising epitaxially-grown conductively-doped monocrystalline semiconductor material 28.

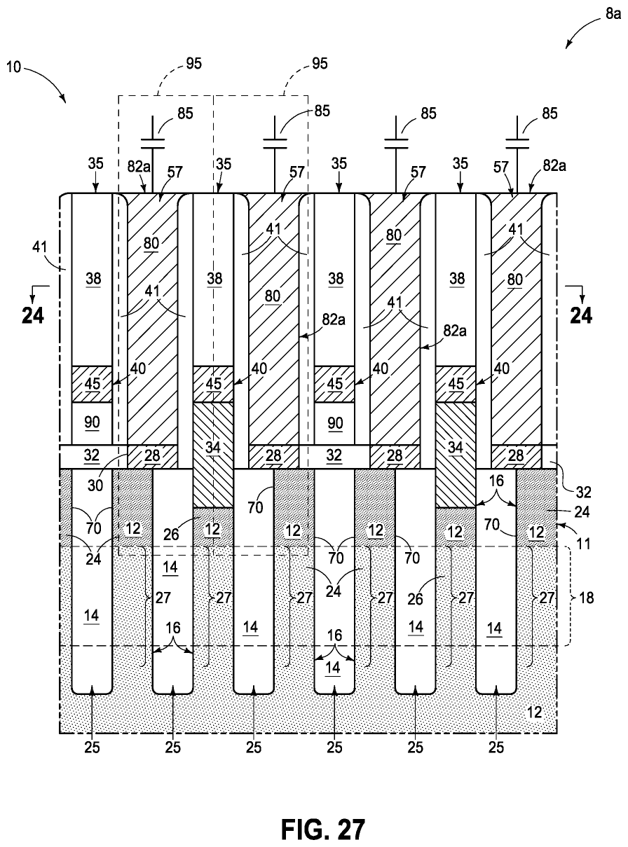

FIG. 27 shows an example alternate construction 8a comprising conductive-via constructions 82a (e.g., comprising materials 80 and 28) that are devoid of conductively-doped semiconducting material 42 (such thereby not being shown). Like numerals from the above-described embodiments have been used where appropriate, with some construction differences being indicated with the suffix “a”.

Any other attribute(s) or aspect(s) as shown and/or described herein with respect to other embodiments may be used in the embodiments shown and described with reference to the above embodiments.

Epitaxially growing material 28 in forming islands 31 as shown and described herein may be used to enlarge the targeting area for individual contact openings 57 thus perhaps increasing area for ohmic contact of one source/drain regions 24 with storage elements 85. Forming of material 42 may be used to further enlarge such area.

Alternate embodiment constructions may result from method embodiments described above, or otherwise. Regardless, embodiments of the invention encompass memory arrays independent of method of manufacture. Nevertheless, such memory arrays may have any of the attributes as described herein in method embodiments. Likewise, the above-described method embodiments may incorporate, form, and/or have any of the attributes described with respect to device embodiments.

In one embodiment, memory circuitry (e.g., 8, 8a) comprises transistors (e.g., 25) individually comprising one source/drain region (e.g., 24) and another source/drain region (e.g., 26). The one and another source/drain regions comprise conductively-doped monocrystalline semiconductive material. A channel region (e.g., 27) is between the one and the another source/drain regions. A conductive gate (e.g., 22) is operatively proximate the channel region. Conducting vias (e.g., 34) are individually directly above and electrically coupled to individual of the another source/drain regions. Digitlines (e.g., 40) are individually above and directly electrically coupled to a plurality of the conducting vias. Conductive-via constructions (e.g., 82, 82a) are individually directly above and directly electrically coupled to individual of the one source/drain regions. Individual of the conductive-via constructions comprise a conductive island (e.g., 31) directly above and directly against the individual one source/drain region. The conductive island comprises conductively-doped monocrystalline semiconductor material (e.g., 28) that is directly against and of the same crystallinity as the conductively-doped monocrystalline semiconductive material of the individual one source/drain region. The conductively-doped monocrystalline semiconductor material at least predominantly has greater conductivity-increasing-dopant therein than is at least predominantly in the individual one source/drain region.

In one embodiment, conducting material (e.g., 42 and/or 80) is directly above and directly electrically coupled to the conductive island. The conducting material is of different composition (e.g., at least 80) from that of the conductively-doped monocrystalline semiconductor material.

In one embodiment, conductively-doped semiconducting material (e.g., 42) is directly above and directly against the conductively-doped monocrystalline semiconductor material of the conductive island. The conductively-doped semiconducting material where so directly against extends laterally-outward beyond the conductively-doped monocrystalline semiconductor material of the conductive island (e.g., beyond a side 43). Conductive metal material (e.g., 80) is directly above and directly against the conductively-doped semiconducting material.

Storage elements (e.g., 85) are individually electrically coupled to the individual conductive-via constructions.

Any other attribute(s) or aspect(s) as shown and/or described herein with respect to other embodiments may be used.

The above processing(s) or construction(s) may be considered as being relative to an array of components formed as or within a single stack or single deck of such components above or as part of an underlying base substrate (albeit, the single stack/deck may have multiple tiers). Control and/or other peripheral circuitry for operating or accessing such components within an array may also be formed anywhere as part of the finished construction, and in some embodiments may be under the array (e.g., CMOS under-array). Regardless, one or more additional such stack(s)/deck(s) may be provided or fabricated above and/or below that shown in the figures or described above. Further, the array(s) of component s may be the same or different relative one another in different stacks/decks and different stacks/decks may be of the same thickness or of different thicknesses relative one another. Intervening structure may be provided between immediately-vertically-adjacent stacks/decks (e.g., additional circuitry and/or dielectric layers). Also, different stacks/decks may be electrically coupled relative one another. The multiple stacks/decks may be fabricated separately and sequentially (e.g., one atop another), or two or more stacks/decks may be fabricated at essentially the same time.

The assemblies and structures discussed above may be used in integrated circuits/circuitry and may be incorporated into electronic systems. Such electronic systems may be used in, for example, memory modules, device drivers, power modules, communication modems, processor modules, and application-specific modules, and may include multilayer, multichip modules. The electronic systems may be any of a broad range of systems, such as, for example, cameras, wireless devices, displays, chip sets, set top boxes, games, lighting, vehicles, clocks, televisions, cell phones, personal computers, automobiles, industrial control systems, aircraft, etc.

In this document unless otherwise indicated, “elevational”, “higher”, “upper”, “lower”, “top”, “atop”, “bottom”, “above”, “below”, “under”, “beneath”, “up”, and “down” are generally with reference to the vertical direction. “Horizontal” refers to a general direction (i.e., within 10 degrees) along a primary substrate surface and may be relative to which the substrate is processed during fabrication, and vertical is a direction generally orthogonal thereto. Reference to “exactly horizontal” is the direction along the primary substrate surface (i.e., no degrees there-from) and may be relative to which the substrate is processed during fabrication. Further, “vertical” and “horizontal” as used herein are generally perpendicular directions relative one another and independent of orientation of the substrate in three-dimensional space. Additionally, “elevationally-extending” and “extend(ing) elevationally” refer to a direction that is angled away by at least 45° from exactly horizontal. Further, “extend(ing) elevationally”, “elevationally-extending”, “extend(ing) horizontally”, “horizontally-extending” and the like with respect to a field effect transistor are with reference to orientation of the transistor's channel length along which current flows in operation between the source/drain regions. For bipolar junction transistors, “extend(ing) elevationally” “ elevationally-extending”, “extend(ing) horizontally”, “horizontally-extending” and the like, are with reference to orientation of the base length along which current flows in operation between the emitter and collector. In some embodiments, any component, feature, and/or region that extends elevationally extends vertically or within 10° of vertical.

Further, “directly above”, “directly below”, and “directly under” require at least some lateral overlap (i.e., horizontally) of two stated regions/materials/components relative one another. Also, use of “above” not preceded by “directly” only requires that some portion of the stated region/material/component that is above the other be elevationally outward of the other (i.e., independent of whether there is any lateral overlap of the two stated regions/materials/components). Analogously, use of “below” and “under” not preceded by “directly” only requires that some portion of the stated region/material/component that is below/under the other be elevationally inward of the other (i.e., independent of whether there is any lateral overlap of the two stated regions/materials/components).

Any of the materials, regions, and structures described herein may be homogenous or non-homogenous, and regardless may be continuous or discontinuous over any material which such overlie. Where one or more example composition(s) is/are provided for any material, that material may comprise, consist essentially of, or consist of such one or more composition(s). Further, unless otherwise stated, each material may be formed using any suitable existing or future-developed technique, with atomic layer deposition, chemical vapor deposition, physical vapor deposition, epitaxial growth, diffusion doping, and ion implanting being examples.

Additionally, “thickness” by itself (no preceding directional adjective) is defined as the mean straight-line distance through a given material or region perpendicularly from a closest surface of an immediately-adjacent material of different composition or of an immediately-adjacent region. Additionally, the various materials or regions described herein may be of substantially constant thickness or of variable thicknesses. If of variable thickness, thickness refers to average thickness unless otherwise indicated, and such material or region will have some minimum thickness and some maximum thickness due to the thickness being variable. As used herein, “different composition” only requires those portions of two stated materials or regions that may be directly against one another to be chemically and/or physically different, for example if such materials or regions are not homogenous. If the two stated materials or regions are not directly against one another, “different composition” only requires that those portions of the two stated materials or regions that are closest to one another be chemically and/or physically different if such materials or regions are not homogenous. In this document, a material, region, or structure is “directly against” another when there is at least some physical touching contact of the stated materials, regions, or structures relative one another. In contrast, “over”, “on”, “adjacent”, “along”, and “against” not preceded by “directly” encompass “directly against” as well as construction where intervening material(s), region(s), or structure(s) result(s) in no physical touching contact of the stated materials, regions, or structures relative one another.

Herein, regions-materials-components are “electrically coupled” relative one another if in normal operation electric current is capable of continuously flowing from one to the other and does so predominately by movement of subatomic positive and/or negative charges when such are sufficiently generated. Another electronic component may be between and electrically coupled to the regions-materials-components. In contrast, when regions-materials-components are referred to as being “directly electrically coupled”, no intervening electronic component (e.g., no diode, transistor, resistor, transducer, switch, fuse, etc.) is between the directly electrically coupled regions-materials-components.

Any use of “row” and “column” in this document is for convenience in distinguishing one series or orientation of features from another series or orientation of features and along which components have been or may be formed. “Row” and “column” are used synonymously with respect to any series of regions, components, and/or features independent of function. Regardless, the rows may be straight and/or curved and/or parallel and/or not parallel relative one another, as may be the columns. Further, the rows and columns may intersect relative one another at 90° or at one or more other angles (i.e., other than the straight angle).

The composition of any of the conductive/conductor/conducting materials herein may be conductive metal material and/or conductively-doped semiconductive/semiconductor/semiconducting material. “Metal material” is any one or combination of an elemental metal, any mixture or alloy of two or more elemental metals, and any one or more metallic compound(s).

Herein, any use of “selective” as to etch, etching, removing, removal, depositing, forming, and/or formation is such an act of one stated material relative to another stated material(s) so acted upon at a rate of at least 2:1 by volume. Further, any use of selectively depositing, selectively growing, or selectively forming is depositing, growing, or forming one material relative to another stated material or materials at a rate of at least 2:1 by volume for at least the first 75 Angstroms of depositing, growing, or forming.

Unless otherwise indicated, use of “or” herein encompasses either and both.

### CONCLUSION

In some embodiments, a method used in forming memory circuitry comprises forming transistors of individual memory cells. The transistors individually comprise one source/drain region and another source/drain region. The one and another source/drain regions comprise conductively-doped monocrystalline semiconductive material. A channel region is between the one and the another source/drain regions. A conductive gate is operatively proximate the channel region. Masking material is formed directly above the one and another source/drain regions. The masking material has openings there-through that extend to and are individually directly above individual of the one source/drain regions. Conductively-doped monocrystalline semiconductor material is epitaxially grown from the conductively-doped monocrystalline semiconductive material of the individual one source/drain regions within individual of the openings to form conductive islands that are individually directly above and directly against the individual one source/drain regions in the individual openings. Storage elements of the individual memory cells are formed. The storage elements individually are above and electrically coupled to the individual one source/drain regions through individual of the conductive islands comprising the epitaxially-grown conductively-doped monocrystalline semiconductor material.

In some embodiments, memory circuitry comprising transistors individually comprise one source/drain region and another source/drain region. The one and another source/drain regions comprise conductively-doped monocrystalline semiconductive material. A channel region is between the one and the another source/drain regions. A conductive gate is operatively proximate the channel region. Conducting vias are individually directly above and electrically coupled to individual of the another source/drain regions. Digitlines are individually above and directly electrically coupled to a plurality of the conducting vias. Conductive-via constructions are individually directly above and directly electrically coupled to individual of the one source/drain regions. Individual of the conductive-via constructions comprise a conductive island directly above and directly against the individual one source/drain region. The conductive island comprises conductively-doped monocrystalline semiconductor material directly against and of the same crystallinity as the conductively-doped monocrystalline semiconductive material of the individual one source/drain region. The conductively-doped monocrystalline semiconductor material at least predominantly has greater conductivity-increasing-dopant therein than is at least predominantly in the individual one source/drain region. Conducting material is directly above and directly electrically coupled to the conductive island. The conducting material is of different composition from that of the conductively-doped monocrystalline semiconductor material. Storage elements are individually electrically coupled to the individual conductive-via constructions.

In some embodiments, memory circuitry comprising transistors individually comprise one source/drain region and another source/drain region. The one and another source/drain regions comprise conductively-doped monocrystalline semiconductive material. A channel region is between the one and the another source/drain regions. A conductive gate is operatively proximate the channel region. Conducting vias are individually directly above and electrically coupled to individual of the another source/drain regions. Digitlines are individually above and directly electrically coupled to a plurality of the conducting vias. Conductive-via constructions are individually directly above and directly electrically coupled to individual of the one source/drain regions. Individual of the conductive-via constructions comprise a conductive island directly above and directly against the individual one source/drain region. The conductive island comprises conductively-doped monocrystalline semiconductor material directly against and of the same crystallinity as the conductively-doped monocrystalline semiconductive material of the individual one source/drain region. The conductively-doped monocrystalline semiconductor material at least predominantly has greater conductivity-increasing-dopant therein than is at least predominantly in the individual one source/drain region. Conductively-doped semiconducting material is directly above and directly against the conductively-doped monocrystalline semiconductor material of the conductive island. The conductively-doped semiconducting material where so directly against extends laterally-outward beyond the conductively-doped monocrystalline semiconductor material of the conductive island. Conductive metal material is directly above and directly against the conductively-doped semiconducting material. Storage elements are individually electrically coupled to the individual conductive-via constructions.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1. A method used in forming memory circuitry, comprising:
forming transistors of individual memory cells, the transistors individually comprising:
one source/drain region and another source/drain region, the one and another source/drain regions comprising conductively-doped monocrystalline semiconductive material;
a channel region between the one and the another source/drain regions; and
a conductive gate operatively proximate the channel region;
forming masking material directly above the one and another source/drain regions, the masking material having openings there-through that extend to and are individually directly above individual of the one source/drain regions;
epitaxially growing conductively-doped monocrystalline semiconductor material from the conductively-doped monocrystalline semiconductive material of the individual one source/drain regions within individual of the openings to form conductive islands that are individually directly above and directly against the individual one source/drain regions in the individual openings; and
forming storage elements of the individual memory cells, the storage elements individually being above and electrically coupled to the individual one source/drain regions through individual of the conductive islands comprising the epitaxially-grown conductively-doped monocrystalline semiconductor material.

2. The method of claim 1 wherein the masking material is insulative and remains in a finished-circuitry construction.

3. The method of claim 1 wherein the masking material masks the another source/drain regions during the epitaxially growing so no conductively-doped monocrystalline semiconductor material grows therefrom.

4. The method of claim 1 wherein the epitaxially growing forms the conductively-doped monocrystalline semiconductor material to at least predominantly have greater conductivity-increasing-dopant therein than is at least predominantly in the individual one source/drain region.

5. The method of claim 4 wherein the greater conductivity-increasing-dopant is by a factor of at least 10.

6. The method of claim 4 wherein the conductively-doped monocrystalline semiconductor material and the conductively-doped monocrystalline semiconductive material are of the same composition but for quantity of the conductivity-increasing-dopant.

7. The method of claim 6 wherein the same composition at least predominantly comprises elemental silicon.

8. The method of claim 1 wherein the epitaxially growing forms the conductively-doped monocrystalline semiconductor material to extend laterally-outward beyond a longest side of the individual one source/drain regions.

9. The method of claim 1 wherein the epitaxially growing forms the conductively-doped monocrystalline semiconductor material to extend laterally-outward beyond a longitudinal end of the individual one source/drain regions.

10. The method of claim 1 wherein the epitaxially growing forms the conductively-doped monocrystalline semiconductor material to:
extend laterally-outward beyond a longest side of the individual one source/drain regions; and
extend laterally-outward beyond a longitudinal end of the individual one source/drain regions.

11. The method of claim 1 comprising forming conducting material directly above and directly electrically coupled to the individual conductive islands, the conducting material being of different composition from that of the conductively-doped monocrystalline semiconductor material.

12. The method of claim 11 wherein the conducting material comprises:
conductively-doped semiconducting material directly above and directly against the conductively-doped monocrystalline semiconductor material of the conductive island; and
conductive metal material directly above and directly against the conductively-doped semiconducting material.

13. The method of claim 12 wherein the conductively-doped semiconducting material where directly against the individual one source/drain regions extends laterally-outward of the conductively-doped monocrystalline semiconductor material of the conductive island.

14. The method of claim 12 wherein the epitaxially growing of the conductively-doped monocrystalline semiconductor material forms the conductively-doped monocrystalline semiconductor material to extend laterally-outward beyond a longest side of the individual one source/drain regions.

15. The method of claim 12 wherein the epitaxially growing of the conductively-doped monocrystalline semiconductor material forms the conductively-doped monocrystalline semiconductor material to extend laterally-outward beyond a longitudinal end of the individual one source/drain regions.

16. The method of claim 12 wherein the epitaxially growing of the conductively-doped monocrystalline semiconductor material forms the conductively-doped monocrystalline semiconductor material to:
extend laterally-outward beyond a longest side of the individual one source/drain regions; and
extend laterally-outward beyond a longitudinal end of the individual one source/drain regions.

17. The method of claim 12 comprising forming conductively-doped semiconducting material atop the epitaxially-grown conductively-doped monocrystalline semiconductor material of the conductive island.

18. The method of claim 17 wherein the conductively-doped semiconducting material extends laterally-outward beyond a side of the epitaxially-grown conductively-doped monocrystalline semiconductor material of the conductive island.

19. Memory circuitry comprising:
transistors individually comprising:
one source/drain region and another source/drain region, the one and another source/drain regions comprising conductively-doped monocrystalline semiconductive material;
a channel region between the one and the another source/drain regions; and
a conductive gate operatively proximate the channel region;
conducting vias that are individually directly above and electrically coupled to individual of the another source/drain regions;
digitlines that are individually above and directly electrically coupled to a plurality of the conducting vias;
conductive-via constructions that are individually directly above and directly electrically coupled to individual of the one source/drain regions, individual of the conductive-via constructions comprising:
a conductive island directly above and directly against the individual one source/drain region, the conductive island comprising conductively-doped monocrystalline semiconductor material directly against and of the same crystallinity as the conductively-doped monocrystalline semiconductive material of the individual one source/drain region, the conductively-doped monocrystalline semiconductor material at least predominantly having greater conductivity-increasing-dopant therein than is at least predominantly in the individual one source/drain region; and
conducting material directly above and directly electrically coupled to the conductive island, the conducting material being of different composition from that of the conductively-doped monocrystalline semiconductor material; and
storage elements that are individually electrically coupled to the individual conductive-via constructions.

20. Memory circuitry comprising:
transistors individually comprising:
one source/drain region and another source/drain region, the one and another source/drain regions comprising conductively-doped monocrystalline semiconductive material;
a channel region between the one and the another source/drain regions; and
a conductive gate operatively proximate the channel region;
conducting vias that are individually directly above and electrically coupled to individual of the another source/drain regions;
digitlines that are individually above and directly electrically coupled to a plurality of the conducting vias;
conductive-via constructions that are individually directly above and directly electrically coupled to individual of the one source/drain regions, individual of the conductive-via constructions comprising:
a conductive island directly above and directly against the individual one source/drain region, the conductive island comprising conductively-doped monocrystalline semiconductor material directly against and of the same crystallinity as the conductively-doped monocrystalline semiconductive material of the individual one source/drain region, the conductively-doped monocrystalline semiconductor material at least predominantly having greater conductivity-increasing-dopant therein than is at least predominantly in the individual one source/drain region;
conductively-doped semiconducting material directly above and directly against the conductively-doped monocrystalline semiconductor material of the conductive island, the conductively-doped semiconducting material where so directly against extending laterally-outward beyond the conductively-doped monocrystalline semiconductor material of the conductive island; and
conductive metal material directly above and directly against the conductively-doped semiconducting material; and
storage elements that are individually electrically coupled to the individual conductive-via constructions.
